(19) United States
(12) Patent Application Publication
(10) Pub. No.: US 2024/0387577 A1
(43) Pub. Date: Nov. 21, 2024

(54) OPTICAL SENSOR PACKAGE AND A METHOD FOR FORMING THE SAME

(71) Applicant: STATS ChipPAC Pte. Ltd., Singapore (SG)

(72) Inventors: HyunKyu LEE, Incheon (KR); BumRyul MAENG, Incheon (KR); JiSeon LEE, Incheon (KR)

(21) Appl. No.: 18/668,225

(22) Filed: May 19, 2024

(30) Foreign Application Priority Data
May 19, 2023 (CN) 202310569186.1

(51) Int. Cl. H01L 27/146

(52) U.S. Cl. CPC H01L 27/14618; H01L 27/14632; H01L 27/14636; H01L 27/14687

(57) ABSTRACT

An optical sensor package is disclosed. The package comprises: a package substrate having a front surface and a back surface; an optical sensor mounted on the package substrate, wherein the optical sensor is encapsulated by a first light-pervious encapsulant mold; a light source mounted on the front surface of the package substrate, wherein the light source is encapsulated by a second light-pervious encapsulant mold; a central interposer mounted on the front surface of the package substrate via a support wall and between the optical sensor and the light source, wherein the central interposer and the support wall are light-impervious to prevent the light source from illuminating directly onto the optical sensor; and at least one electronic component mounted on the central interposer, wherein the at least one electronic component is electrically coupled to the optical sensor via a first interconnect that passes through the first light-pervious encapsulant mold.

### TECHNICAL FIELD

The present application generally relates to semiconductor technologies, and more particularly, to an optical sensor package and a method for forming an optical sensor package.

### BACKGROUND OF THE INVENTION

Recently, electric vehicle and automatic driving technologies are rapidly developing. Sensors such as lidar sensors or image sensors are commonly used in automatic driving for detecting environment around a vehicle. The sensors are usually integrated into a semiconductor package having electronic components with other functionalities to make the entire semiconductor package smaller.

In order for avoiding the interference by a light source to an optical sensor in the compact optical sensor package, a blocking frame wall is generally used. The blocking frame wall may stand between the light source and the optical sensor such that the light source cannot illuminate directly onto a light receiving surface of the optical sensor. However, the blocking frame wall increases the size of the optical sensor package.

Therefore, a need exists for further improvement to optical sensor packages.

### SUMMARY OF THE INVENTION

An objective of the present application is to provide an optical sensor package with a compact structure.

According to an aspect of the present application, an optical sensor package is disclosed. The optical sensor package comprises: a package substrate having a front surface and a back surface; an optical sensor mounted on the front surface of the package substrate, wherein the optical sensor is encapsulated by a first light-pervious encapsulant mold; a light source mounted on the front surface of the package substrate, wherein the light source is encapsulated by a second light-pervious encapsulant mold; a central interposer mounted on the front surface of the package substrate via a support wall and between the optical sensor and the light source, wherein the central interposer and the support wall are light-impervious to prevent the light source from illuminating directly onto the optical sensor; and at least one electronic component mounted on the central interposer, wherein the at least one electronic component is electrically coupled to the optical sensor via a first interconnect that passes through the first light-pervious encapsulant mold.

According to another aspect of the present application, there is provided a method for forming an optical sensor package. The method comprises: providing a package substrate having on its front surface an optical sensor and a light source, wherein the optical sensor and the light source are encapsulated by a first light-pervious encapsulant mold and a second light-pervious encapsulant mold, respectively; forming a first through hole in the first light-pervious encapsulant mold to partially expose the optical sensor; forming a second through hole in the second light-pervious encapsulant mold to partially expose the light source; filling in the first and second through holes a conductive material to form a first interconnect and a second interconnect; mounting a central interposer on the front surface of the package substrate via a support wall and between the optical sensor and the light source and connecting the central interposer with the first and second interconnects, wherein the central interposer and the support wall are light-impervious to prevent the light source from illuminating directly onto the optical sensor; and mounting at least one electronic component on the central interposer to electrically couple the at least one electronic component with the optical sensor via the first interconnect and the central interposer and to electrically couple the at least one electronic component with the light source via the second interconnect and the central interposer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate an optical sensor package according to an embodiment of the present application. FIG. 1A is a cross-sectional view of the optical sensor package, and FIG. 1B is a top view of the optical sensor package.

FIGS. 2A to 2I illustrate a method for forming an optical sensor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

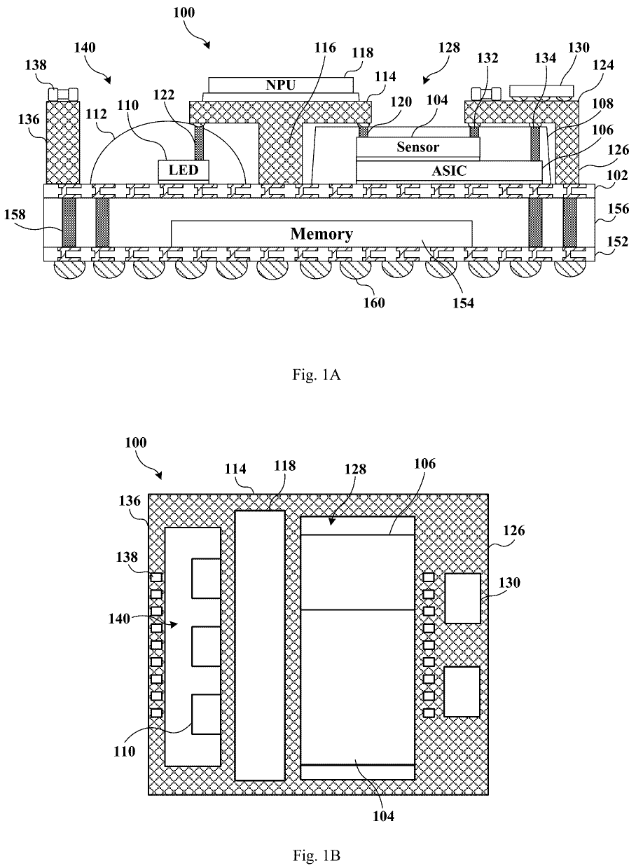

FIGS. 1A and 1B illustrate an optical sensor package 100 according to an embodiment of the present application. FIG. 1A is a cross-sectional view of the optical sensor package 100, and FIG. 1B is a top view of the optical sensor package 100. The optical sensor package 100 integrates therewithin a light source and an optical sensor. The light source can emit to the environment light irradiation such as visible light or infrared light, while the optical sensor can receive light reflected by objects in the environment so as to generate a signal that may reflect the existence and/or movements of the objects. In some embodiments, the optical sensor may be an image sensor, a lidar sensor or any other suitable optical sensors.

As shown in FIG. 1A, the optical sensor package 100 includes a package substrate 102. In some embodiment, the package substrate 102 can provide support and connectivity for the electronic components mounted thereon. By way of example, the package substrate 102 can include a printed circuit board (PCB), a carrier substrate, a semiconductor substrate with electrical interconnections, or a ceramic substrate. In some other examples, the package substrate 102 may include a laminate interposer, a strip interposer, a leadframe, or other suitable substrates. The package substrate 102 has a front surface and a back surface. In some embodiments, almost all the components may be mounted on the front surface of the package substrate 102, while in some alternative embodiments, a portion of the components may be mounted on the back surface of the package substrate 102 to further improve the integration of the entire optical sensor package 100, thereby realizing a compact structure.

In particular, an optical sensor 104 is mounted on the front surface of the package substrate 102. The optical sensor 104 may be an image sensor or other similar types of optical sensors. The optical sensor 104 may have a photosensitive surface that is facing away from the package substrate 102 but towards the environment, so as to collect lights emitted from the environment and towards the optical sensor package 100. In the embodiment, an electronic component such as an application specific integrated circuit (ASIC) chip 106 may be disposed between the optical sensor 104 and the package substrate 102, i.e., the optical sensor 104 is mounted indirectly on the front surface of the package substrate 102 via the ASIC chip 106. The ASIC chip 106 may integrate therewithin certain functionalities such as power supply, signal processing, mode control, etc., to assist and control the operation of the optical sensor 104 and/or some other components of the optical sensor package 100. However, it can be appreciated that the optical sensor 104 may be mounted directly on the front surface of the package substrate 102 without intermediate components. For example, the ASIC chip 106 may be mounted at some other positions of the front surface or the back surface of the package substrate 102. Moreover, as shown in FIGS. 1A and 1B, the ASIC chip 106 may have a bigger size than that of the optical sensor 104 and thus occupy a bigger footprint of the package substrate 102, and thus the optical sensor 104 may be well mounted and supported on a front surface of the ASIC chip 106. In some examples, there may be no direct electrical connection between the optical sensor 104 and the ASIC chip 106, and a bonding material such as an adhesive material may be filled between the optical sensor 104 and the ASIC chip 106. In some other embodiments, electrical connections may be established at the interface between the optical sensor 104 and the ASIC chip 106, as desired.

In an embodiment, the optical sensor 104 and the ASIC chip 106 under the optical sensor 104 may be encapsulated by a first light-pervious encapsulant mold 108, which can protect the optical sensor 104 from external contaminants, damages or shocks. The first light-pervious encapsulant mold 108 may be made of a light-pervious material such as glass, silicone, resin or other suitable materials or composition thereof, and may be formed using a molding process such as injection molding or compression molding.

For image sensors that are generally sensitive to visible light, although natural light may be sufficient during daytime, during nighttime or in a dark environment where the natural light may be of a relative low intensity, image sensors may not generate clear images. In addition, for a lidar sensor, it is desired to emit a specific laser beam to the environment from the lidar sensor and then receive laser reflection from the environment. Accordingly, respective light sources may be desired to be integrated within the optical sensor package 100.

As shown in FIGS. 1A and 1B, a light source 110 such as light emitting diodes (LEDs) is mounted on the front surface of the package substrate 102, for example besides the optical sensor 104. The light source 110 can be encapsulated by a second light-pervious encapsulant mold 112. Similar as the first light-pervious encapsulant mold 108, the second light-pervious encapsulant mold 112 may be made of a light-pervious material such as glass, silicone, resin or other suitable materials or composition thereof, and may be formed using a molding process such as injection molding or compression molding. In the embodiment, the second light-pervious encapsulant mold 112 may be formed with a circular cross section, as shown in FIG. 1A. In this way, lights can be emitted to the environment from the light source 110 in a generally isotropic manner, to cover a broader range of objects in the environment.

Due to the isotropic light emission, light can not only be emitted towards objects in front of the light source 110, but also towards the optical sensor 104 that is besides the light source 110, which may produce undesired glares. In order to avoid the light interferences from the light source 110, a central interposer 114 is mounted on the front surface of the package substrate 102 via a support wall 116, and between the optical sensor 104 and the light source 110. The central interposer 114 and the support wall 116 are both light-impervious to prevent the light source 110 from illuminating directly onto the optical sensor 104. In some embodiments, the central interposer 114 may be formed separately from the support wall 116, while in some other embodiments, the central interposer 114 may be formed together with the support wall 116 as a single piece, for example, in a single molding process or similar processes. In some embodiments, the central interposer 114 may be formed of a silicon-based material or other similar materials, for example, using a semiconductor fabrication process. In some preferred embodiments, the central interposer 114 may be formed of a polymeric material such as epoxy, resin, silicone, or a mixture of two or more polymeric materials and/or other non-polymeric materials, which may be formed with a desired shape and/or internal structures at a lower cost, for example, using a molding process.

The central interposer 114 may have conductive pillars, posts, vias or similar structures that pass through the central interposer 114, thereby providing respective electrical paths between a front surface and a back surface of the central interposer 114.

As shown in FIG. 1A, at least one electronic component 118 such as a neural network processing unit (NPU) is mounted on the central processor 114, or particularly on the front surface of the central processer 114. The electronic component 118 may be electrically coupled to the optical sensor 104 via a first interconnect 120 that passes through the first light-pervious encapsulant mold 108. For example, electrical signals generated by the optical sensor 104 may be transmitted to the electronic component 118 directly through the first interconnect 120 for further processing. In particular, the electronic component 118 may be attached to the central interposer 114 and electrically coupled to the conductive structures in the central interposer 114. At least a portion of these conductive structures can be further coupled to the first interconnect 120, via solder bumps, for example. It can be appreciated that more than one first interconnects 120 may pass through the first light-pervious encapsulant mold 108 to the optical sensor 104, if desired, although only one first interconnect 120 is shown in FIG. 1A. In some embodiments, the first interconnect 120 may be formed by first drilling an opening through the first light-pervious encapsulant mold 108 and then filling within the opening a conductive material such as silver paste. Other alternative ways may be employed to form the first interconnect 120.

It can be seen that, with the light-impervious central interposer 114 disposed between the optical sensor 104 and the light source 110, not only light interference can be significantly reduced, but also more electronic components may be mounted over the package substrate 102 without occupying an additional area of the front surface of the package substrate 102. In some embodiments, the central interposer 114 may be disposed, relative to the front surface of the package substrate 102, higher than the optical sensor 104 and the light source 110, to allow for sufficient space for accommodating them. However, in some alternative embodiment, the central interposer 114 may not be higher than the optical sensor 104 and/or the light source 110, and other ways such as wire bonding may be used to connect the interposer 114 and/or the electronic component 118 with the optical sensor 104. Also, although it is shown in FIG. 1A that the electronic component 118 is electrically coupled to the optical sensor 114 via the first interconnect 120, in some other embodiments, the electronic component 118 on the central interposer 114 may be further electrically coupled to the ASIC chip 106 via another interconnect (not shown) which can either pass through the optical sensor 104 or not pass through it.

In some embodiments, the electronic component 118 on the central interposer 114 may be further electrically coupled to the light source 110 via a second interconnect 122, which may pass through the second light-pervious encapsulant mold 112 over the light source 110. Similar as the first interconnect 120, the second interconnect 122 may be formed by first drilling an opening through the second light-pervious encapsulant mold 112 and then filling within the opening a conductive material such as silver paste. Also, the number of the second interconnect 122 may vary as desired.

In some embodiments, the central interposer 114 and the support wall 116 are structured having an L-shaped cross section, or a T-shaped cross section as shown in FIG. 1A. That is to say, the central interposer 114 may have a greater area than the footprint of the support wall 116 for mounting the electronic component 118 thereon. In some preferred embodiments, the central interposer 114 may partially overlap with the optical sensor 104 and/or the light source 110 when viewed from a vertical direction of the package substrate 102. As such, it is more convenient to form vertical interconnects at the portions of the central interposer 114 that overlap with the optical sensor 104 and the light source 110, respectively. It can be appreciated that the overlapping between the central interposer 114 and the optical sensor 104, or between the central interposer 114 and the light source 110 may not significantly block the light receiving by the optical sensor 104 and the light emission from the light source 110.

In some embodiments, there may be some interconnect structures (not shown) formed within the support wall 116 which can for example extend from the package substrate 102 to the interposer 114. As such, the interposer 114 can be electrically coupled to the package substrate 102, especially conductive patterns on the front surface of the package substrate 102, via interconnect structures in the support wall 116.

Still referring to FIGS. 1A and 1B, other interposer structures may be formed on the front surface of the package substrate 102. For example, a peripheral interposer 124 may be mounted on the front surface of the package substrate 102 via a side wall 126 adjacent to the optical sensor 104. The peripheral interposer 124 may be opposite to the central interposer 114 in relation to the optical sensor 104. The peripheral interposer 124 and the side wall 126 can be light-impervious to reduce light interference from a lateral side of the optical sensor package 100. The central interposer 114 and the peripheral interposer 124 can define together a sensor window 128 that permits light to illuminate therethrough onto the optical sensor 104, as shown in FIG. 1B. Similar as the central interposer 114, at least one other electronic component 130 may be mounted on the peripheral interposer 124, which may be electrically coupled to the optical sensor 104 via a third interconnect 132 that passes through the first light-pervious encapsulant mold 108 and be electrically coupled to the ASIC chip 106 via a fourth interconnect 134 that also passes through the first light-pervious encapsulant mold 108. Also, the number of the third and fourth interconnects may vary as desired. In the embodiment, the peripheral interposer 124 and the side wall 126 are structured having an L-shaped cross section, to reduce the occupation of the area of the package substrate 102. The peripheral interposer 124 can be disposed, relative to the front surface of the package substrate 102, higher than the optical sensor 104 to accommodate the optical sensor 104 and the ASIC chip 106. Preferably, the peripheral interposer 124 may partially overlaps with the optical sensor 104 when viewed from the vertical direction of the package substrate 102. In some preferred embodiments, the peripheral interposer 124 may be formed of a polymeric material or a mixture of two or more polymeric materials and/or other non-polymeric materials.

Similarly, a side wall interposer 136 may be formed adjacent to the light source 110, and opposite to the central interposer 114 in relation to the light source 110. The side wall interposer 136 may have internal interconnect structures that extend from its top surface to its bottom surface, to allow electrical connection between any electronic component 138 mounted thereon and the package substrate 102. The side wall interposer 136 may define with the central interposer a lighting window 140 that permits light to emit therethrough to the environment. In some preferred embodiments, the side wall interposer 136 may be formed of a polymeric material or a mixture of two or more polymeric materials and/or other non-polymeric materials. Furthermore, as shown in FIG. 1B, the central interposer 114, the peripheral interposer 124 and the side wall interposer 136 may be at least partially connected with each other to form a frame with the two windows 128 and 140 topmost of the optical sensor package 100. In this way, these interposers 114, 124 and 136 may be formed as a single piece and attached onto the package substrate 102 in a single operation.

The front side of the package substrate 102 are mounted with the light source 110, the optical sensor 104 and other various components. In some embodiments, the back surface of the package substrate 102 can be further utilized for mounting other structures and/or components. In the embodiment shown in FIG. 1A, at least one backside electronic component such as a memory chip 154 may be attached to the back surface of the package substrate 102, to further improve integration of the optical sensor package 100.

As shown in FIG. 1A, the backside electronic component 154 may be mounted on a front surface of a backside substrate 152 and encapsulated by a backside encapsulant layer 156. Backside interconnects 158 may be formed in the backside encapsulant layer 156 to pass through the backside encapsulant layer 156 and electrically connect the package substrate 102 with the backside substrate 152. The backside encapsulant layer 156 may be further attached onto the back surface of the package substrate 102. In addition, solder bumps 160 may be formed on the back surface of the backside substrate 152. As such, all the electronic components of the optical sensor package 100 may be electrically coupled to the solder bumps and further to an external device or system when the package 100 is connected to the external device or system.

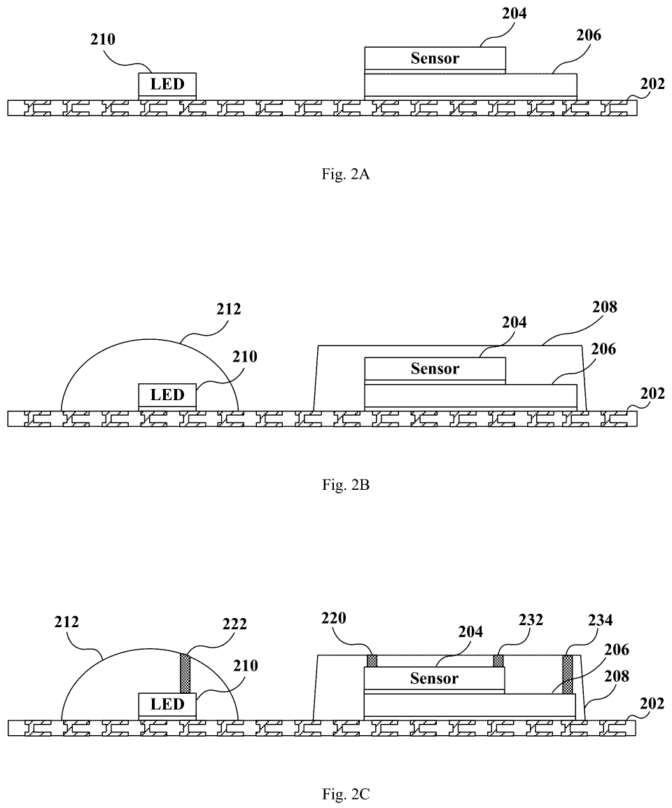

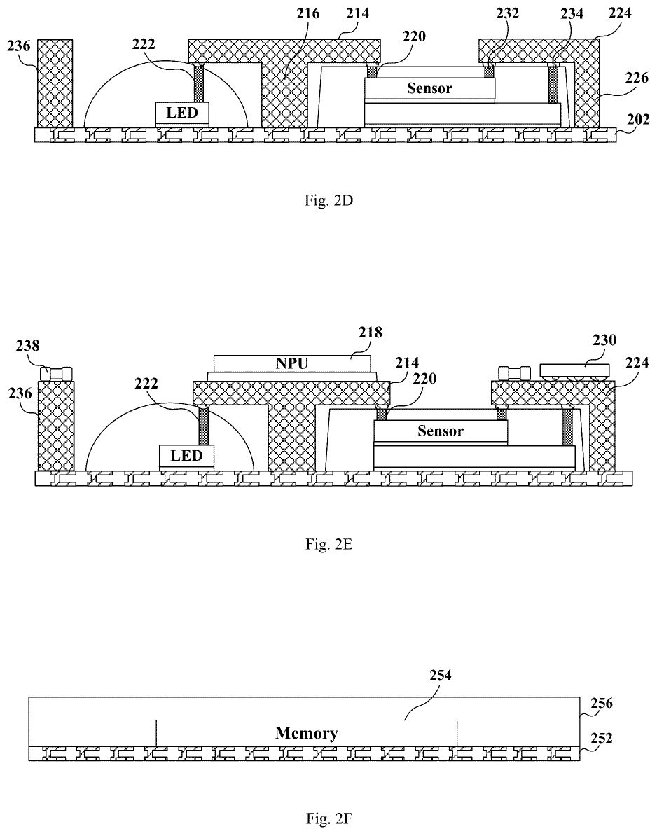

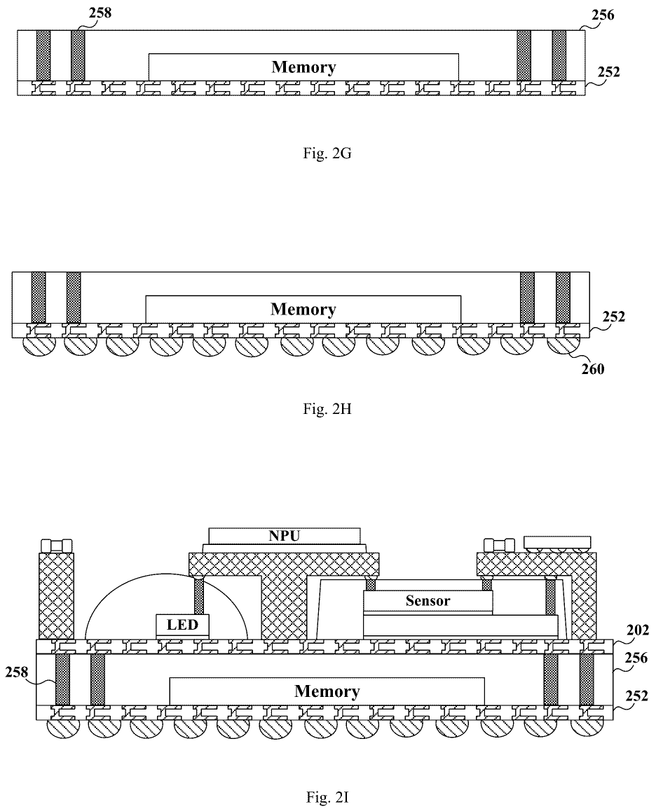

FIGS. 2A to 2I illustrate a method for forming an optical sensor package according to an embodiment of the present application. For example, the method may be used to form the optical sensor package 100 shown in FIGS. 1A and 1B.

As shown in FIG. 2A, a package substrate 202 is provided. The package substrate 202 has a front surface and a back surface which is opposite to the front surface. An optical sensor 204 and a light source 210 are mounted on the front surface of the package substrate 202. In the embodiment, an electronic component such as an application specific integrated circuit (ASIC) chip 206 may be disposed between the optical sensor 204 and the package substrate 202, i.e., the optical sensor 204 is mounted indirectly on the front surface of the package substrate 202 via the ASIC chip 206. In some other embodiments, the optical sensor 204 may be mounted directly on the front surface of the package substrate 206.

Next, as shown in FIG. 2B, a first light-pervious encapsulant mold 208 may be formed to encapsulate the optical sensor 204 and the ASIC chip 206, and a second light-pervious encapsulant mold 212 may be formed to encapsulant the light source 210. The light-pervious encapsulant mold 208 and 212 may be formed using a molding process such as injection molding or compression molding, and can be formed simultaneously or separately. The first and second light-pervious encapsulant molds 208 and 212 may not be in contact with each other, and thus a gap may be formed therebetween on the package substrate 202.

Next, as shown in FIG. 2C, various through holes may be formed in the first light-pervious encapsulant mold 208 and 212 to partially expose the optical sensor 204, the ASIC chip 206 and the light source 210, or particularly expose certain contact pads on the respective top surfaces of these components. In some examples, the through holes may be formed using laser ablation, or any other suitable processes. A conductive material such as silver paste may be filled in the through holes to form respective interconnects such as an interconnect 222 that passes through the second light-pervious encapsulant mold 212, and interconnects 220, 232 and 234 that pass through the first light-pervious encapsulant mold 208. In this way, the optical sensor 204, the ASIC chip 206 and the light source 210 may be electrically coupled to other components from its top side via the interconnects 220, 222, 232 and 234, respectively.

Next, as shown in FIG. 2D, a central interposer 214 may be mounted on the front surface of the package substrate 202 via a support wall 216. The central interposer 214 is thus in the gap between the optical sensor 204 and the light source 210. In some embodiments, the support wall 216 may not have internal conductive structures such as interconnect pillars, vias or redistribution layers, and thus it may be attached onto the package substrate 202 via a non-conductive adhesive material. In some alternative embodiments, the support wall 216 may have internal conductive structures that extend from the interposer 214 to its bottom surface, and thus the support wall 216 may be attached onto the package substrate 202 via solder bumps or similar conductive structures, to allow for an electrical path between the central interposer 214 and the package substrate 202. The central interposer 214 and the support wall 216 are light-impervious.

In addition, the central interposer 214 may have contact pads or other similar conductive patterns on its bottom surface. When the central interposer 214 is mounted onto the package substrate 202, the contact pads of the central interposer 214 may be aligned with the interconnects 220 and 222. A solder material or other similar conductive adhesive material may be formed, for example, by printing, between the contact pads of the central interposer 214 and the interconnects 220 and 222, so as to electrically connect the central interposer 214 with the interconnects 220 and 222. Preferably, the central interposer 214 may partially overlap with the optical sensor and the light source when viewed from a vertical direction of the package substrate 202, to allow for easy alignment of the contact pads of the central interposer 214 and the interconnects 220 and 222. A curing process may be performed to cure any of the adhesive material or solder material.

In some embodiments, the central interposer 214 and the support wall 216 are structured having an L-shaped or T-shaped cross section, to provide a good optical isolation between the light source and the optical sensor as well as to accommodate the components thereunder. For example, the central interposer 214 may be disposed, relative to the front surface of the package substrate 202, higher than the optical sensor and the light source.

In some embodiments, the central interposer 214 and the support wall 216 may be formed as a single piece, such that they can be mounted onto the package substrate 202 at the same time. In an alternative embodiment, the central interposer 214 and the support wall 216 may be two pieces. In that case, the support wall 216 may be first attached onto the package substrate 202, and then the interposer 214 may be attached onto a top surface of the support wall 216.

Certain other interposers may be mounted on the front surface of the package substrate 202, to further improve integration of the optical sensor package to be formed. For example, as shown in FIG. 2D, a peripheral interposer 224 may be mounted on the front surface of the package substrate 202 via a side wall 226, which is adjacent to the optical sensor 204. Furthermore, the peripheral interposer 224 may be connected with the interconnects 232 and 234. In some embodiments, the peripheral interposer 224 and the side wall 226 are structured having an L-shaped cross section. Preferably, the peripheral interposer 224 can partially overlap with the optical sensor 204 when viewed from the vertical direction of the package substrate 202, to facilitate the alignment of certain contact pads of the peripheral interposer 224 with the interconnects 232 and 234. The peripheral interposer 224 may be disposed, relative to the front surface of the package substrate 202, higher than the optical sensor. Similarly, a side wall interposer 236 may be formed adjacent to the light source, and opposite to the central interposer 214 in relation to the light source. The side wall interposer 236 may have internal interconnect structures that extend from its top surface to its bottom surface. In some embodiments, the central interposer 214, the peripheral interposer 224 and the side wall interposer 236 may be at least partially connected with each other to form a frame with the two windows that expose the optical sensor and the light source respectively. In this way, these interposers 214, 224 and 236 may be formed as a single piece and attached onto the package substrate 202 in a single operation. In some alternative embodiments, the central interposer 214, the peripheral interposer 224 and the side wall interposer 236 may be individual pieces that can be mounted onto the package substrate 202 separately. In some preferred embodiments, the central interposer 214, the peripheral interposer 224 and the side wall interposer 236 may be formed of a polymeric material or a mixture of two or more polymeric materials and/or other non-polymeric materials.

Afterwards, as shown in FIG. 2E, various electronic components may be mounted on the interposers 214, 224 and 236. For example, an electronic component 218 such as an NPU may be mounted on the central interposer 214, which can be electrically coupled to at least one of the light source and the optical sensor via the central interposer 214 and the interconnects 220 and 222. At least one electronic component 230 may be mounted on the peripheral interposer 224 to be electrically coupled to the optical sensor and the electronic component thereunder via the peripheral interposer 224 and the interconnects 232 and 234. Similarly, an electronic component such as a resistor or a capacitor 238 may be mounted on the side wall interposer 238, and can be electrically coupled to the package substrate 202 via the side wall interpose 238. It can be appreciated that the electronic components may be mounted on the interposers using any suitable surface mounting techniques such as solder mounting or direct bonding.

Next, as shown in FIG. 2F, a backside substrate 252 may be provided. The backside substrate 252 has a front surface and a back surface. At least one backside electronic component such as a memory 254 may be mounted on the front surface of the backside substrate 252. A backside encapsulant layer 256 may be formed on the front surface of the backside substrate 252 to encapsulate the at least one backside electronic component.

As shown in FIG. 2G, backside interconnects 258 may be formed in the backside encapsulant layer 256, for example, by first laser ablation and then conductive material filling. The backside interconnects 258 may pass through the backside encapsulant layer 256, i.e., extend from a bottom surface to a top surface of the backside encapsulant layer 256. Depending on the electrical connection desired to be established between the backside substrate 252 and the package substrate, one or more backside interconnects 258 may be formed. After that, as shown in FIG. 2H, solder bumps 260 may be formed on the back surface of the backside substrate 252.

At last, the backside substrate 252, with the components and structures formed thereon, may be attached onto the package substrate 202 to form the optical sensor package. In particular, the backside encapsulant layer 256 may be attached onto the back surface of the package substrate 202, to electrically couple the package substrate 202 with the backside substrate 252 via the backside interconnects 258. In this way, most or all of the electronic components in the optical sensor package can be electrically coupled together to form an optical sensor system.

While the optical sensor package of the present application is described in conjunction with corresponding figures, it will be understood by those skilled in the art that modifications and adaptations to the semiconductor package may be made without departing from the scope of the present invention.

The discussion herein includes numerous illustrative figures that show various portions of an optical sensor package and a method for forming the optical sensor package. For illustrative clarity, such figures do not show all aspects of each example semiconductor package. Any of the example optical sensor packages provided herein may share any or all characteristics with any or all other optical sensor packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An optical sensor package, comprising:
a package substrate having a front surface and a back surface;
an optical sensor mounted on the front surface of the package substrate, wherein the optical sensor is encapsulated by a first light-pervious encapsulant mold;
a light source mounted on the front surface of the package substrate, wherein the light source is encapsulated by a second light-pervious encapsulant mold;
a central interposer mounted on the front surface of the package substrate via a support wall and between the optical sensor and the light source, wherein the central interposer and the support wall are light-impervious to prevent the light source from illuminating directly onto the optical sensor; and
at least one electronic component mounted on the central interposer, wherein the at least one electronic component is electrically coupled to the optical sensor via a first interconnect that passes through the first light-pervious encapsulant mold.

2. The optical sensor package of claim 1, wherein the central interposer and the support wall are structured having an L-shaped or T-shaped cross section.

3. The optical sensor package of claim 2, wherein the central interposer is disposed, relative to the front surface of the package substrate, higher than the optical sensor and the light source.

4. The optical sensor package of claim 1, wherein the at least one electronic component is further electrically coupled to the light source via a second interconnect that passes through the second light-pervious encapsulant mold.

5. The optical sensor package of claim 4, wherein the central interposer partially overlaps with the optical sensor and the light source when viewed from a vertical direction of the package substrate.

6. The optical sensor package of claim 4, wherein the first interconnect is made of a conductive material filled in the first light-pervious encapsulant mold, and the second interconnect is made of a conductive material filled in the second light-pervious encapsulant mold.

7. The optical sensor package of claim 1, further comprising:
a peripheral interposer mounted on the front surface of the package substrate via a side wall adjacent to the optical sensor, wherein the peripheral interposer and the side wall are light-impervious, and the central interposer and the peripheral interposer define together a sensor window that permits light to illuminate therethrough onto the optical sensor.

8. The optical sensor package of claim 7, further comprising:
at least one other electronic component mounted on the peripheral interposer, wherein the at least one other electronic component is electrically coupled to the optical sensor via a third interconnect that passes through the first light-pervious encapsulant mold.

9. The optical sensor package of claim 8, wherein the peripheral interposer and the side wall are structured having an L-shaped cross section.

10. The optical sensor package of claim 9, wherein the peripheral interposer is disposed, relative to the front surface of the package substrate, higher than the optical sensor.

11. The optical sensor package of claim 9, wherein the peripheral interposer partially overlaps with the optical sensor when viewed from a vertical direction of the package substrate.

12. The optical sensor package of claim 1, further comprising:
a backside substrate having a front surface and a back surface,
at least one backside electronic component mounted on the front surface of the backside substrate;
a backside encapsulant layer formed on the front surface of the backside substrate and encapsulating the at least one backside electronic component, wherein the backside encapsulant layer is attached onto the back surface of the package substrate;
backside interconnects formed in the backside encapsulant layer, wherein the backside interconnects are configured such that they pass through the backside encapsulant layer and electrically connect the package substrate with the backside substrate; and
solder bumps formed on the back surface of the backside substrate.

13. A method for forming an optical sensor package, comprising:
providing a package substrate having on its front surface an optical sensor and a light source, wherein the optical sensor and the light source are encapsulated by a first light-pervious encapsulant mold and a second light-pervious encapsulant mold, respectively;
forming a first through hole in the first light-pervious encapsulant mold to partially expose the optical sensor;
forming a second through hole in the second light-pervious encapsulant mold to partially expose the light source;
filling in the first and second through holes a conductive material to form a first interconnect and a second interconnect;
mounting a central interposer on the front surface of the package substrate via a support wall and between the optical sensor and the light source and connecting the central interposer with the first and second interconnects, wherein the central interposer and the support wall are light-impervious to prevent the light source from illuminating directly onto the optical sensor; and
mounting at least one electronic component on the central interposer to electrically couple the at least one electronic component with the optical sensor via the first interconnect and the central interposer and to electrically couple the at least one electronic component with the light source via the second interconnect and the central interposer.

14. The method of claim 13, wherein the central interposer and the support wall are structured having an L-shaped or T-shaped cross section.

15. The method of claim 14, wherein the central interposer is disposed, relative to the front surface of the package substrate, higher than the optical sensor and the light source.

16. The method of claim 14, wherein the central interposer partially overlaps with the optical sensor and the light source when viewed from a vertical direction of the package substrate.

17. The method of claim 13, wherein the central interposer and the support wall are formed as a single piece.

18. The method of claim 13, wherein the conductive material is silver paste.

19. The method of claim 13, further comprising:
forming a third through hole in the first light-pervious encapsulant mold to partially expose the optical sensor;
filling in the third through hole a conductive material to form a third interconnect;
mounting a peripheral interposer on the front surface of the package substrate via a side wall and adjacent to the optical sensor and connecting the peripheral interposer with the third interconnect, and
mounting at least one other electronic component on the peripheral interposer to electrically couple the at least one other electronic component with the optical sensor via the third interconnect.

20. The method of claim 13, further comprising:
providing a backside substrate having a front surface and a back surface,
mounting at least one backside electronic component on the front surface of the backside substrate;
forming a backside encapsulant layer on the front surface of the backside substrate to encapsulate the at least one backside electronic component,
forming backside interconnects in the backside encapsulant layer, wherein the backside interconnects pass through the backside encapsulant layer;
forming solder bumps on the back surface of the backside substrate; and
attaching the backside substrate onto the package substrate with the backside encapsulant layer attached onto the back surface of the package substrate, to electrically couple the package substrate with the backside substrate via the backside interconnects.
